(19) United States
(12) Patent Application Publication
(10) Pub. No.: US 2017/0096732 A1
(43) Pub. Date: Apr. 6, 2017

(54) MULTILAYER COATINGS ON SUBSTRATES

(71) Applicant: HEWLETT-PACKARD DEVELOPMENT COMPANY, L.P., HOUSTON, TX (US)

(72) Inventors: KUAN-TING WU, TAIPEI CITY (TW); YU-CHUAN KANG, TAIPEI CITY (TW); YAO-WEN FAN, TAIPEI CITY (TW)

(21) Appl. No.: 15/308,303

(22) PCT Filed: Jun. 23, 2014
(86) PCT No.: PCT/US2014/043689

§ 371 Date: Nov. 1, 2016

(51) Int. Cl. C23C 14/00; C25D 13/06; G06F 1/16; C23C 14/46; C23C 14/35; C25D 13/02; C25D 13/22

(52) U.S. Cl. CPC C23C 14/0036; C25D 13/02; C25D 13/06; C25D 13/22; C23C 14/46; C23C 14/35; G06F 1/1656

(57) ABSTRACT

Example implementations relate to manufacturing multilayer coatings on substrates. In examples, a substrate with an electrically conducting surface may be provided. A first layer of a first material may be electrophoretically deposited on at least a portion of the electrically conducting surface of the substrate. A second layer of a second, electrically conducting material may be deposited on at least a portion of the first layer using physical vapor deposition. A third layer of a third material may be electrophoretically deposited on at least a portion of the second layer.

### BACKGROUND

Coatings for decorative and functional purposes am commonly used to modify substrate surfaces. Two modern methods for producing coatings include electrophoretic deposition and physical vapor deposition. These processes are capable of producing relatively thin coatings that may have desirable properties. Physical vapor deposition, in particular, can be used to create metallic coatings with high luster and strong wear characteristics. These characteristics may be important in various application, including for protective and functional surfaces in electronic devices and computing hardware.

### BRIEF DESCRIPTION OF THE DRAWINGS

The following detailed description references the drawings, wherein:

FIG. 1A is a flowchart of an example method for depositing a multilayer coating on a substrate;

FIG. 1B is a flowchart of an example method for depositing a multilayer coating on a substrate including pretreating the substrate and depositing a functional coating;

FIG. 2 is a cross-section diagram of an example multilayer coating deposited on a substrate;

FIG. 3 is a block diagram of an example computing device having a casing with a multilayer coating deposited on the substrate of the casing;

### DETAILED DESCRIPTION

Thin films and coatings are becoming increasingly significant in various industries, including applications in microelectronics, optics, nano-technology, magnetics, electro-optics, and electrochemistry. Coating processes and technologies allow for the manipulation of physical properties of materials by altering the surface properties of the materials, in particular, physical vapor deposition (PVD) is a well-known process for providing thin metallic coatings with high luster and superior wear.

However, the properties of some PVD coatings may be affected by the characteristics of the substrate onto which the PVD coating Is applied. Generally, because PVD coatings are thin, they are influenced by undesirable surface properties of the substrate. For example, a PVD coating applied to a rough surface with high porosity may appear dull because the PVD coating conforms to the surface on which it is applied. Additionally, certain substrates, such as some magnesium alloys, have highly reactive surfaces that tend to be oxidized. For these reasons, effort has been spent to develop methods for preparing surfaces to be better suited for PVD and other coating methods. Some examples include painting methods and plating methods. However, substrate preparation processes are often time consuming and expensive and may not be suitable for many applications.

Examples disclosed herein provide for depositing multilayer coatings on substrates. In example Implementations, a first layer of a first material is electrophoretically deposited (ED) on the surface of the substrate. A second layer of a second material, which typically provides the desired characteristics of the coating, is deposited on the first layer by PVD. A third layer of a third material is then phoretically deposited on the second layer. The first layer may level the surface of the substrate and provide a surface better suited for PVD layers, in this manner, preparing the substrate by first electrophoretically depositing a first layer may allow PVD layers to be effectively deposited on the exterior of substrates, including substrates that traditionally perform poorly for PVD. Additionally, a third ED layer may protect the PVD layer and provide an additional surface for further layers, such as function coatings.

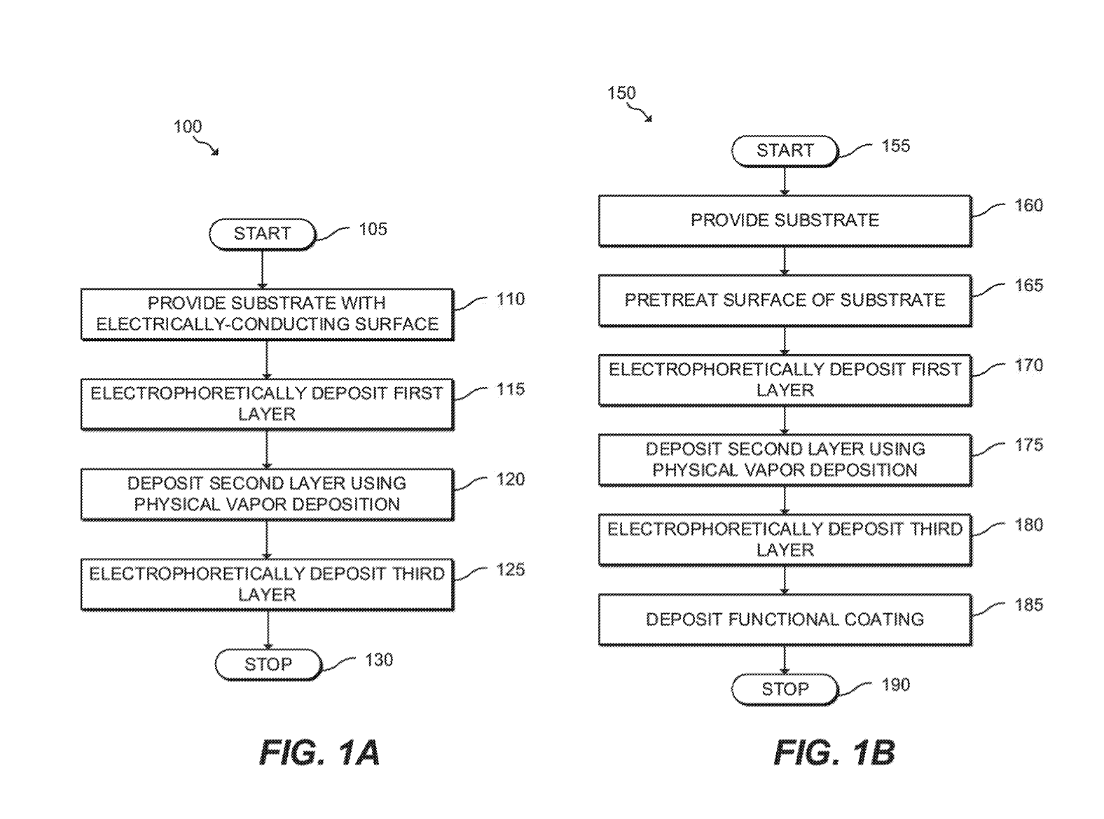

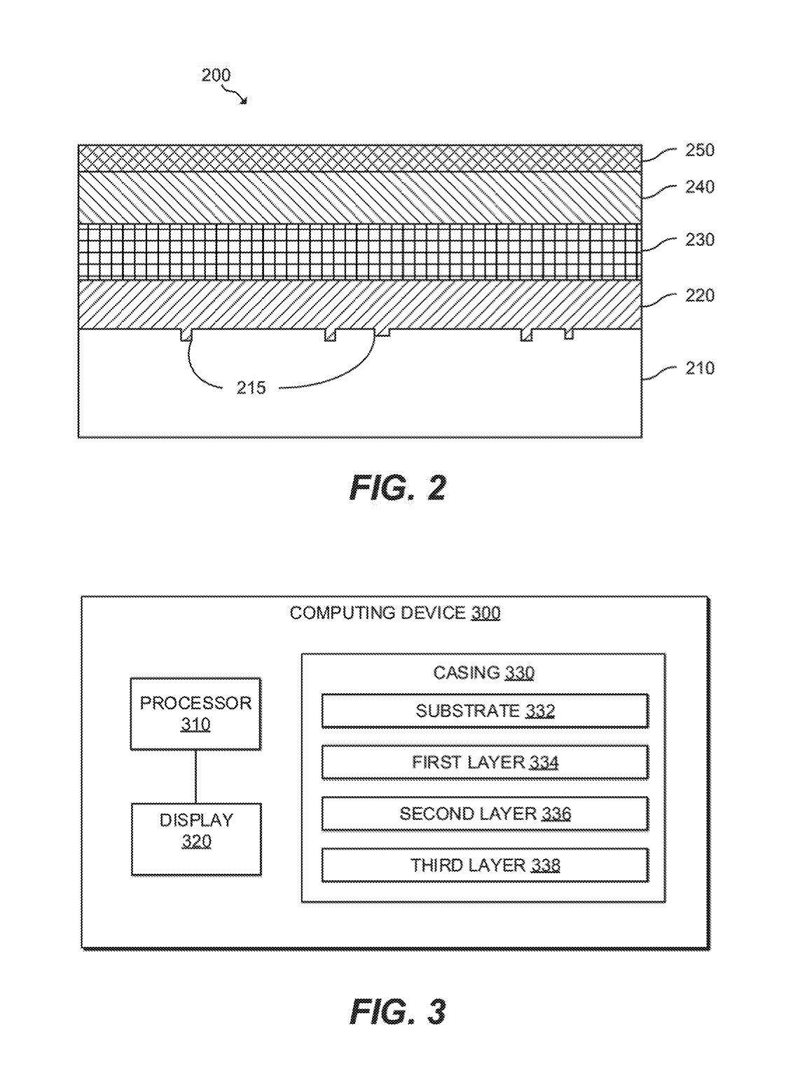

Referring now to the drawings, FIG. 1A depicts a flowchart of an example method 100 for depositing a multilayer coating on a substrate, which may include block 110 for providing a substrate with an electrically conducting surface, block 115 for electrophoretically depositing a first layer on the electrically conducting surface of the substrate, block 120 for depositing a second layer on the first layer using PVD, and block 130 for electrophoretically depositing a third layer on the second layer.

Method 100 may begin in block 105 and proceed to block 110, where a substrate with an electrically conducting surface may be provided. A substrate may be a material on which method 100 and example processes described herein are conducted. Various substrates with electrically conducting surfaces may be suitable for use in conjunction with method 100. For example, the substrate may be a metal or metal alloy. In such examples, the substrate may be inherently conductive and no further processing of the substrate may be required before moving to block 115. In some examples, the substrate may have an alloy of aluminum, magnesium, lithium, zinc, titanium, niobium, nickel, chromium, copper, or combinations thereof. Some substrates may contain metals that are highly reactive, such as alloys that tend to be oxidized or reduced when exposed to the atmosphere. In example implementations, magnesium-lithium (Mg—Li) alloys are used as the substrate for implementation of methods described herein.

In some other examples, the substrate may include a material that is inherently nonconductive. For example, the substrate may be a composite material having a nonconductive material and a conducting material forming the surface. Typical composite materials may have a polymer core and metal surfaces. The substrate may contain multiple layers, where some layers may contain conducting materials such as metal alloys and where some layers may contain non-conducting materials such as polymers, fibers, or hybrid materials, fn other instances, the substrate may not contain any inherently conducting materials. In such instances, the substrate may be pretreated, which is described in detail in relation to block 185 of method 150 shown in FIG. 18.

After providing a substrate, method 100 may proceed to block 115, where a first layer of a first material is electrophoretically deposited on at feast a portion of the electrically conducting surface of the substrate provided in block 110. Electrophoretic deposition is an industrial process where colloidal particles suspended in a liquid medium migrate under the influence of an electric field and are deposited onto a conducting surface immersed in the medium, such as the electrically conducting surface of the substrate. Various ED processes may be used for the execution of block 115, including electrocoating, e-coating, cathodic electroposition, arid anodic electrodeposition. ED may be a relatively quick process that produces coatings of uniform thickness.

Suitable first materials for the first layer may include a variety of materials, depending on the application. For example, the first material may have at least one of a metal, a polymer, a ceramic, and pigments and dies. In some implementations, a thermoplastic polymer may be used. Examples polymers for the first material include acrylics, polyurethanes, epoxies, and combinations thereof. A polymeric material as the first layer provides leveling properties along with the ability to control thickness, which may eliminate or reduce the need for abrasive buffing or other treatments. In one example, block 115 may involve providing a bath cell containing a colloidal suspension of an acrylic material, immersing a portion of the substrate info the bath to expose desired parts of the electrically conducting surface of the substrate to the suspension, and providing an electric charge to tie bath cell. The substrate, when immersed in the suspension under charge, may serve as an anode or cathode, attracting the suspended materials. The thickness of the resulting coating on the substrate may vary depending upon the charge, the length of time during which the substrate is immersed, the type of material used in the suspension, and other factors. Furthermore, in some examples, the first layer may be polymerized after coating the electrically conducting surface of the substrate.

Deposition of the first layer may provide beneficial effects to the electrically conducting surface of the substrate. In implementations where the substrate surface is reactive, the first layer may stabilize the reactive surface. A first layer with a polymeric material may be particularly effective in stabilizing metallic surfaces that tend to be oxidized or reduced by shielding the surface from exposure to the environment. Alternatively or in addition, the substrate may contain pores, cavities, bumps, or other surface imperfections. The first layer may fill porous cavities as well as mend other imperfections, providing an even surface for the next steps of the processes described herein.

In some examples, the first layer may be electrophoretically deposited onto a portion of the electrically conducting surface of the substrate. In other examples, the first layer may be deposited onto entire surfaces of the substrate. Because the first layer may serve the dual purpose of protecting the substrate and providing a suitable surface for PVD on top of tie first layer, the portion of the electrically conducting surface that may be coated by the first layer may depend on the intended application. Because only the portions of the electrically conducting surface that is immersed in an electrophoretic cell will be coated during the ED process, the extent of deposition of the first layer on the electrically conducting surface of the substrate may be effectively controlled.

After electrophoretically depositing the first layer, method 100 may proceed to block 120, where a second layer of a second material, which is electrically conducting, is deposited on at least a portion of the first layer using physical vapor deposition. PVD generally describes a vacuum deposition method used to deposit thin films by condensation of a vaporized form of a desired material onto a target surface. Various PVD processes may be used for the execution of block 120, including ion-beam sputtering, reactive sputtering, ion-assisted deposition, high-target-utilization sputtering, high-power impulse magnetron sputtering, gas flow sputtering, and chemical vapor deposition.

Suitable second materials for the second layer may include a variety of materials, depending on the application. Because a third layer may be electrophoretically deposited on top of the second layer, the second material may generally be electrically conducting. Example suitable metallic materials for the second layer include titanium, chromium, nickel, zinc, zirconium, manganese, copper, aluminum, tin, molybdenum, tantalum, tungsten, hafnium, gold, vanadium, silver, platinum, and alloy combinations thereof. Generally, the second layer provides many of the desired physical properties for the multilayer coating. For example, the second layer may provide a metallic luster appearance for the multilayer coating, in another example, a specific second material may provide a desired resistivity to the multilayer coating.

In some examples, the second layer may be deposited onto a portion of the first layer. In other examples, the second layer may be deposited onto the entirety of the first layer. Because the second layer may serve the dual purpose of providing desired physical appearance and properties and of providing a suitable surface for electrophoretically depositing the third layer, the portion of the first layer that may be coated by the second layer may depend on the intended application. The extent of deposition of the second layer on the first layer may be effectively controlled by setting appropriate parameters for the PVD process.

After depositing the second layer, method 100 may proceed to block 125, where a third layer of a third material is electrophoretically deposited on at least a portion of the second layer. The third layer may provide additional benefits, particular to the second layer, including enhancing corrosion resistance, improving chemical resistance, adding color to tie multilayer coating, or functioning as an electrical insulator. The third layer may be deposited by the various ED processes described in relation to block 115 or other processes. Furthermore, the third material may be any number of suitable materials, including metals, polymers, and ceramics. The third layer may stabilize the surface of the second layer and may coat a part of or the entirety of the second layer, depending on application and as controlled by the ED process.

After electrophoretically depositing the third layer, method 100 may proceed to block 130, where method 100 may stop. The multilayer coating provided by method 100 may provide advantages to the substrate. For example, corrosion and chemical resistance may be improved. The addition of the first layer may also Improve adhesion of the second layer because metal coatings tend to form strong adhesion with polymeric coatings. Furthermore, a polymeric third layer may enhance the appearance of the second layer, such as by increasing gloss, and may protect the second layer in a similar manner as the first layer protects the substrate.

FIG. 1B depicts a flowchart of an example method 150 for depositing a multilayer coating on a substrate including pretreating the substrate and depositing a functional coating, which may include block 180 for providing a substrate, block 185 for pretreating a surface of the substrate, block 170 for electrophoretically depositing a first layer on the pretreated surface of the substrate, block 175 for depositing a second layer on the first layer using PVD. block 180 for electrophoretically depositing a third layer on the second layer, and block 185 for depositing a functional coating on the third layer,

Method 150 may start in block 155 and proceed to block 160, where a substrate may be provided. As described in relation to block 110 of example method 100, the substrate may have a variety of materials. For example, the substrate may he a metal or metal alloy. In some other examples, the substrate may include a material that is inherently nonconductive. For example, the substrate may be a composite material having a nonconductive material and a conducting material forming the surface. Typical composite materials may have a polymer core and metal surfaces. The substrate may contain multiple layers, where some layers may contain conducting materials such as metal alloys and where some layers may contain non-conducting material such as polymers. In other instances, the substrate may not contain any inherently conducting materials.

After providing the substrate, method 150 may proceed to block 185, where a surface of the substrate is pretreated. The surface of the substrate may be pretested for various purposes, including preparing the surface for the subsequent blocks of method 150. For example, in instances where the substrate provided in block 180 lacks an electrically conducting surface onto which a multilayer coating is to be deposited, an electrically conducting material may be coated onto the surface of the substrate to provide a surface for electrophoretically depositing the first layer. In other examples, where the substrate has a metallic surface, a polishing or cleaning process may be performed to finish the metallic surface prior to proceeding in method 150. In particular, the substrate may be cleaned to remove residues, oils, and other contaminants that may affect adhesion and uniformity of the multilayer coating.

After preheating the substrate, method 150 may proceed to blocks 170, 175, and 180, where a first layer of a first material is electrophoretically deposited on at least a portion of the pretreated surface of the substrate, a second layer of a second material, which is electrically conducting, is deposited on at least a portion of the first layer using physical vapor deposition, and a third layer of a third material is electrophoretically deposited on at least a portion of the second layer. Various processes and materials may be utilized in the execution of blocks 170, 175, and 180, details of which are described in relation to blocks 115, 120, and 125 of method 100, respectively.

After electrophoretically depositing the third layer, method 150 may proceed to block 185, where a functional coating is deposited on at least a portion of the third layer. A functional coating may be applied to influence fie surface properties of the multilayer coating, such as adhesion, wettability, corrosion resistance, wear resistance, and touch. Specific examples may include anti-fingerprint, soft touch, anti-bacterial, or anti-smudge coatings. Functional coatings may be particularly advantageous in application involving exposure to physical or chemical contact. For example, soft touch may be widely applicable in mobile device applications. Functional coatings may be deposited onto a portion of the entirety of the third layer, depending on the application.

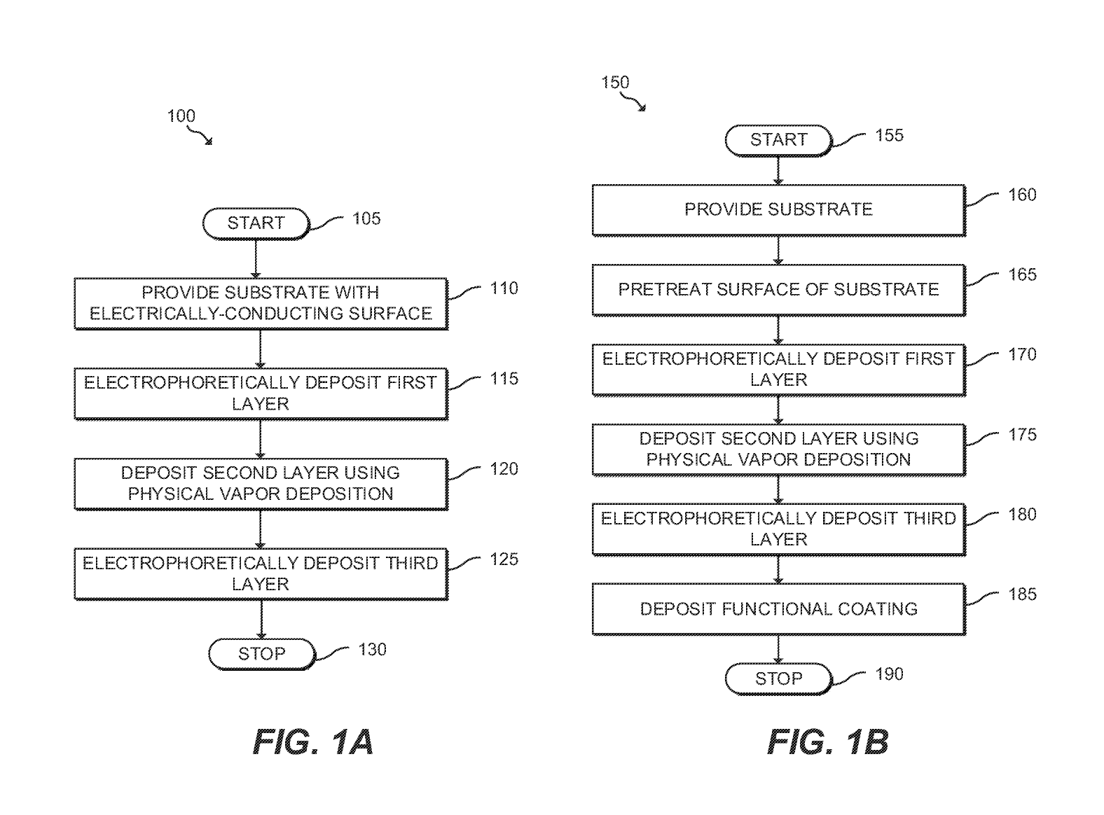

FIG. 2 depicts a cross-section diagram of an example multilayer coating 200, which may include a substrate 210, a first layer 220 of a first material, a second layer 230 of a second material, a third layer 240 of a third material, and a functional coating 250. First layer 220 may be electrophoretically deposited on substrate 210, second layer 230 may be deposited on first layer 220 using physical vapor deposition, and third layer 240 may be electrophoretically deposited on second layer 230. Although in this example, multilayer coating 200 is described as manufactured using example method 150 of FIG. 1B, it should be noted that other processes may be suitable for manufacturing multilayer 200, including method 100 of FIG. 1A.

Substrate 210 may be a material onto which multilayer coating 200 may he applied. Substrate 210 may have an electrically conducting surface, such as a metal or metal alloy. Alternatively, an electrically conducting surface may be provided onto substrate by pretreatment such as described in relation to block 185 of method 150. In some examples, substrate 210 may have a reactive metal surface, such as one of a magnesium alloy. In addition or in other examples, substrate 210 may contain surface cavities, pits, pores, bumps, or other surface imperfections represented in FIG. 2 as 215. In some examples, the substrate may be a composite material having a nonconductive material and a conducting material. Typical composite materials may have a polymer core and metal surfaces. The substrate may contain multiple layers, where some layers may contain conducting materials such as metal alloys and where some layers may contain non-conducting material such as polymers, fibers, or hybrid materials.

First layer 220 may contain a first material and may be electrophoretically deposited on a portion or the entirety of the electrically conducting surface of substrate 210. First layer 220 may be deposited using a variety of ED processes and may have a variety of materials, including polymers such as acrylics, polyurethanes, and epoxies. First layer 220 may provide a number of benefits to substrate 210, including providing a level surface and stabilizing reactive surfaces. As shown in FIG. 2, first layer 220 may also fill surface cavities 215 on substrate 210, resulting in a smoother surface that may be better suited for further coating or have a better appearance.

Second layer 230 may contain a second material and may be deposited on a portion or the entity of first layer 220. Second layer 230 may be deposited using a variety of PVD processes. The second material may include a variety of materials, depending on the application. Because third layer 240 may be electrophoretically deposited on top of second layer 230, the second material may generally he electrically conducting. Example suitable metallic materials for the second layer include titanium, chromium, nickel, zinc, zirconium, manganese, copper, aluminum, tin, molybdenum, tantalum, tungsten, hafnium, gold, vanadium, silver, platinum, and alloy combinations thereof. Generally, second layer 230 provides many of the desired physical properties for the multilayer coating.

Third layer 240 may contain a third material and may be electrophoretically deposited on a portion or the entirety of second layer 230. Third layer 240 may be deposited using a variety of ED processes and may have a variety of materials, including polymers such as acrylics, polyurethanes, and epoxies. Third layer 240 may provide additional benefits, particular to second layer 230, including enhancing corrosion resistance, improving chemical resistance, adding color to multilayer coating 200, or functioning as an electrical insulator. Furthermore, third layer 240 may stabilize the surface of the second layer.

Functional coating 250 may be deposited on a portion or the entirety of third layer 240 and may influence the surface properties of multilayer coating 200. For example, functional coating 250 may affect the adhesion, wettability, corrosion resistance, wear resistance, and touch of multilayer coating 200. Specific examples of functional coating 250 may include anti-fingerprint, soft touch, anti-bacterial, or anti-smudge coats. Functional coatings may be particularly advantageous in application involving exposure to physical or chemical contact For example, soft touch may be widely applicable in mobile device applications.

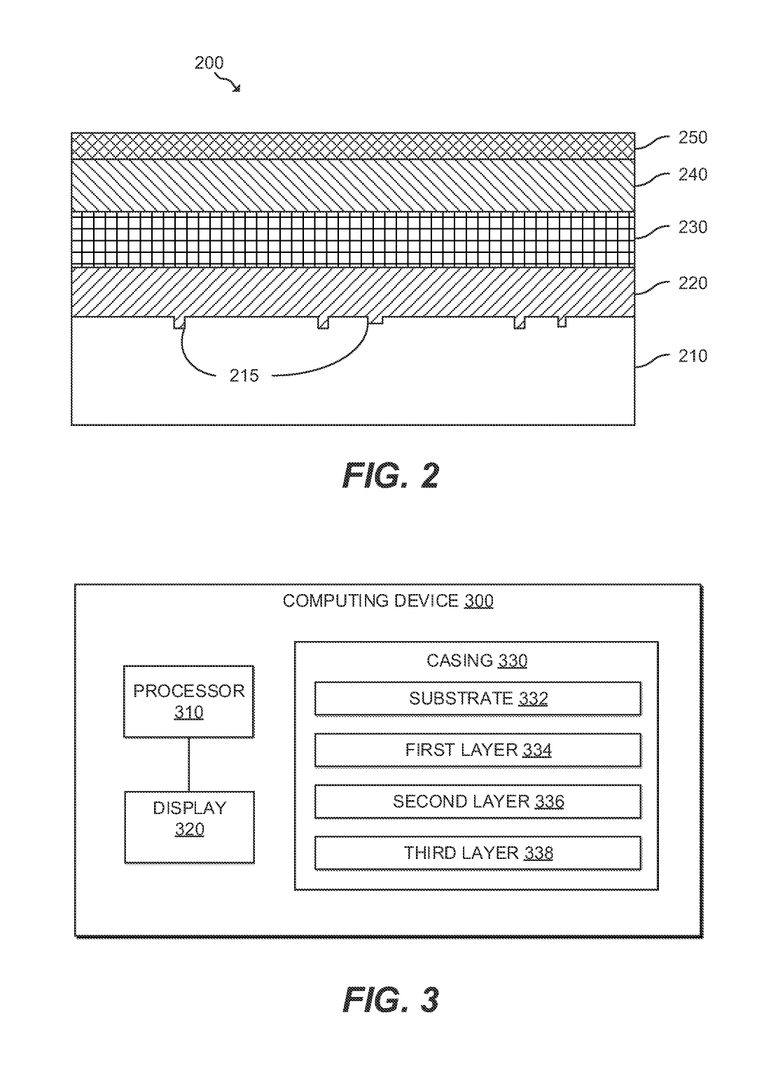

FIG. 3 depicts a block diagram of an example computing device 300 having a casing 330 with a multilayer coating deposited on the substrate 332 of the casing. Computing device 300 may be, for example, a notebook or desktop computer, a mobile device such as a mobile phone or tablet, a local area network (LAM) server, a web server, a cloud-hosted server, or any other electronic device that has a casing. In the implementation of FIG. 3, computing device 300 includes a processor 310 and a display 320.

Processor 310 may be one or more central processing units (CPUs), semiconductor-based microprocessors, and/or other hardware devices suitable for retrieval and execution of instructions stored in a memory device such as random access memory, machine-readable storage medium, or another form of computer data storage. Display 320 may be an electronic visual display for presentation of computing output, typically through a graphic user interface. For example, display 320 may be a monitor for displaying the screen of a computer or mobile device. In some examples, display 320 may have an input feature in addition to output, such as in touchscreen applications.

Casing 330 may be a physical structure that may enclose components of a computing device. In some implementations, casing 300 may protect the interior components of a device, such as a mobile phone, that is frequently exposed to contact. In such instances, casing 300 may sometimes be referred to ask a cover, case, base, or chassis. In some instances, casing 330 may be in the interior of another cover or casing. For example, a computing device with an exterior case may contain various components that may themselves be protected by a casing, such as casing 330.

Casing 330 may include substrate 332, first layer 334, second layer 338, and third layer 338, Substrate 332 may have a variety of materials as described herein. In mobile applications, size and weight of computing device 300 may need to be minimized. Certain light but reactive alloys, such as magnesium-lithium alloys are desirable as casings for mobile devices, in such cases, an electrophoretically deposited first layer 334 of a first material such as an acrylic polymer may stabilize the surface of substrate 332. Second layer 336 of a second material may be deposited on first layer 334 using physical vapor depositing. Second layer 338 may provide desired characteristics, such as metallic luster. Third layer 338 of a third material may be electrophoretically deposited on second layer 338 to protect second layer 336, provide an exterior appearance, and/or modify the surface properties of multilayer coating 330. Furthermore, in some examples, a functional coating may be applied on top of third layer 338 to further modify the surface of multilayer coating 300.

What is claimed is:

1. A method of manufacturing a multilayer coating, comprising;
providing a substrate with an electrically conducting surface;
electrophoretically depositing a first layer of a first material on at least a portion of the electrically conducting surface of the substrate;
depositing, using physical vapor deposition, a second layer of a second material on at least a portion of the first layer, wherein the second material is electrically conducting; and
electrophoretically depositing a third layer of a third material on at least a portion of the second layer.

2. The method of claim 1, wherein the electrically conducting surface comprises a metal alloy.

3. The method of claim 2, wherein the electrically conducting surface of the substrate comprises a reactive metal and wherein electrophoretically depositing the first layer stabilizes the reactive metal.

4. The method of claim 2, wherein the substrate comprises an alloy of at least one of aluminum, magnesium, lithium, zinc, titanium, niobium, and copper.

5. The method of claim 1, wherein electrophoretically depositing the first layer fills porous cavities on the surface of the substrate.

6. The method of claim 1, wherein the first material and the third material each comprises at least one of a metal, a polymer, a ceramic, pigments, and dyes.

7. The method of claim 1, wherein depositing the second layer is performed using at least one of ion-beam sputtering, reactive sputtering, ion-assisted deposition, high-target-utilization sputtering, high-power impulse magnetron sputtering, gas flow sputtering, and chemical vapor deposition.

8. The method of claim 1, wherein the substrate comprises a composite, the composite comprising a metal and a polymer.

9. The method of claim 1, further comprising pretreating the surface of the substrate.

10. The method of claim 1, further comprising depositing a functional coating on at least a portion of the third layer.

11. A coated substrate, comprising:
a first layer of a first material electrophoretically deposited on a metallic surface of a substrate;
a second layer of a second material deposited, using physical vapor deposition, on at least a portion of the first layer, wherein the second material is electrically conducting;
a third layer of a third material electrophoretically deposited on at least a portion of the second layer; and
a functional coating deposited on at least a portion of the third layer.

12. The coated surface of claim 11, wherein the metallic surface of the substrate is reactive, and wherein the metallic surface is stabilized by the first layer electrophoretically deposited on the metallic surface.

13. The coated surface of claim 11, wherein the metallic surface of the substrate comprises porous cavities that are filled by the first layer electrophoretically deposited on the metallic surface.

14. The coated surface of claim 11, wherein the metallic surface of the substrate comprises a magnesium alloy.

15. A computing device, comprising:
a processor;
a display; and
a casing that comprises a substrate with a metallic surface, a first layer of a first material electrophoretically deposited on the metallic surface, a second layer of a second material that is electrically conducting deposited on the first layer using physical vapor deposition, and a third layer of a third material electrophoretically deposited on the second layer.
